(19) United States
(12) Patent Application Publication
(10) Pub. No.: US 2023/0118837 A1
(43) Pub. Date: Apr. 20, 2023

(54) SEMICONDUCTOR DEVICE, METHOD FOR MANUFACTURING SAME AND APPLICATION THEREOF

(71) Applicant: CHANGXIN MEMORY TECHNOLOGIES, INC., Hefei City (CN)

(72) Inventor: TZUNG-HAN LEE, Hefei (CN)

(21) Appl. No.: 17/698,106

(22) Filed: Mar. 18, 2022

Related U.S. Application Data
(63) Continuation of application No. PCT/CN2022/071632, filed on Jan. 12, 2022.

(30) Foreign Application Priority Data
Oct. 18, 2021 (CN) 202111208074.0

(51) Int. Cl. H01L 29/78; H01L 29/10; H01L 21/8238

(52) U.S. Cl. CPC H01L 29/7848; H01L 29/1054; H01L 21/823807

(57) ABSTRACT

Provided are a semiconductor device, a method for manufacturing it and an application thereof. The semiconductor device includes a substrate; a semiconductor material layer located on the substrate and covering a part of the substrate; a gate located on the semiconductor material layer and the substrate not covered by the semiconductor material layer; in which, along an extending direction of the gate, a width of the semiconductor material layer is smaller than a width of the substrate, and a carrier mobility of a material of the semiconductor material layer is different from a carrier mobility of a material of the substrate.

### CROSS-REFERENCE TO RELATED APPLICATIONS

The present application is a continuation application of International Application No. PCT/CN2022/071632, filed on Jan. 12, 2022, which claims priority to Chinese Patent Application No. 202111208074.0, filed on Oct. 18, 2021. The disclosures of International Application No. PCT/CN2022/071632 and Chinese Patent Application No. 202111208074.0 are hereby incorporated by reference in their entireties.

### BACKGROUND

With continuous development of integrated circuit industry, silicon-based integrated circuit technology, which is driven by equal proportion reduction of metal oxide semiconductor (MOS) devices, has entered nanometer size. However, further reduction of transistor size also has an impact on transistor performance, such as the generation of Gate Induced Drain Leakage (GIDL) current, which affects device performance

### SUMMARY

The disclosure relates to the technical field of the semiconductor, in particular to a semiconductor device, a method for manufacturing same and application thereof.

Embodiments of the disclosure provide a semiconductor device, a method for manufacturing it and an application thereof.

According to a first aspect of the embodiment of the disclosure, a semiconductor device is provided. The semiconductor device includes a substrate; a semiconductor material layer located on the substrate and covering part of the substrate; a gate located on the semiconductor material layer and the substrate not covered by the semiconductor material layer; in which along an extension direction of the gate, a width of the semiconductor material layer is smaller than a width of the substrate, and a carrier mobility of a material of the semiconductor material layer is different from a carrier mobility of a material of the substrate.

According to a second aspect of the embodiment of the disclosure, a method for manufacturing a semiconductor device is provided. The method for manufacturing a semiconductor device includes: providing a substrate; forming a semiconductor material layer on the substrate, in which the semiconductor material layer covers a part of the substrate; forming a gate on the semiconductor material layer and the substrate not covered by the semiconductor material layer; in which, along an extension direction of the gate, a width of the semiconductor material layer is smaller than a width of the substrate, and a carrier mobility of a material of the semiconductor material layer is different from a carrier mobility of a material of the substrate.

According to a third aspect of the embodiment of the disclosure, an application of a semiconductor device in a circuit is provided, the circuit includes: a main word line, a sub word line, a word line driving circuit and a voltage control module, in which the voltage control module includes the semiconductor device as described in anyone of the above embodiments.

The semiconductor device includes a source terminal, a drain terminal and a gate terminal; the source terminal is connected to a high-level signal, the drain terminal is connected to a main word line, and the gate terminal is connected to a standby signal.

The word line driving circuit is connected between the main word line and the sub word line.

The voltage control module is configured to reduce a voltage output to the word line driving circuit in the case that a standby state occurs.

According to a fourth aspect of the embodiment of the disclosure, a method for driving a circuit is provided, the method for driving a circuit is applied to the circuit described in anyone of the embodiments of the third aspect of the disclosure; the method includes: controlling the semiconductor device to be in the off state in the case that the standby state does not occur; and controlling the semiconductor device to be in the semi-conducting state in the case that the standby state occurs, so as to increase an equivalent resistance of the semiconductor device and reduce a voltage output to the word line driving circuit.

### BRIEF DESCRIPTION OF THE DRAWINGS

FIG. 1 is a top view of a semiconductor device provided by an embodiment of the disclosure;

FIG. 2 is a sectional view taken along the direction of the dotted line A-A′ in FIG. 1;

FIG. 3 is a sectional view taken along the direction of the dotted line B-B′ in FIG. 1;

FIG. 4 is a graph showing the relationship between gate voltage and drain current;

FIG. 5 is a schematic flow chart of a method for manufacturing a semiconductor device provided by an embodiment of the disclosure;

FIGS. 6A to 6G are schematic structural diagrams of a semiconductor device provided by an embodiment of the disclosure in the manufacturing process; and

FIG. 7 is a circuit diagram of a circuit provided by an embodiment of the disclosure.

### DETAILED DESCRIPTION

Exemplary embodiments of the disclosure will be described in more detail below with reference to the accompanying drawings. Although exemplary embodiments of the disclosure are shown in the drawings, it should be understood that the disclosure can be realized in various forms and should not be limited by the specific embodiments set forth herein. On the contrary, these embodiments are provided to enable a more thorough understanding of the disclosure and to fully convey the scope of the disclosure to those skilled in the art.

In the following description, numerous specific details are given in order to provide a more thorough understanding of the disclosure. However, it will be obvious to those skilled in the art that the disclosure can be practiced without one or more of these details. In other examples, in order to avoid confusion with this disclosure, some technical features known in the art are not described; that is, all the features of the actual embodiment are not described here, and well-known functions and structures are not described in detail.

In the drawings, the dimensions of layers, regions and elements and their relative dimensions may be exaggerated for clarity. The same reference numeral refers to that same element throughout.

It should be understood that when an element or layer is referred to as “on”, “adjacent to”, “connected to” or “coupled to” other elements or layers, it may be directly on, adjacent to, connected to or coupled to other elements or layers, or there may be intervening elements or layers. On the contrary, when an element is referred to as directly on, directly adjacent to, directly connected to or directly coupled to other elements or layers, there is no intervening element or layer. It should be understood that although the terms first, second and third can be used to describe various elements, components, regions, layers and/or parts, these elements, components, regions, layers and/or parts should not be limited by these terms. These terms are only used to distinguish one element, component, region, layer or part from another element, component, region, layer or part. Therefore, the first element, component, region, layer or part discussed below can be expressed as the second element, component, region, layer or part without departing from the teachings of the disclosure. When the second element, component, region, layer or part is discussed, it does not mean that the first element, component, region, layer or part necessarily exists in this disclosure.

Spatial terms such as under, below, the lower, beneath, on, above, etc. can be used here to describe the relationship between one element or feature shown in the figure and other elements or features. It should be understood that in addition to the orientations shown in the figures, the spatial relationship term is intended to include different orientations of devices in use and operation. For example, if the device in the drawing is flipped over, then the element or feature described as “under other elements” or “under them” or “below them” will be oriented to be “above” other elements or features. Therefore, the exemplary terms “under . . . ” and “below . . . ” may include both the up and down orientations. The device can be otherwise oriented (rotated by 90 degrees or other orientations) and the spatial descriptors used herein should be interpreted accordingly.

The terminology used here is only for the purpose of describing specific embodiments and is not a limitation of the disclosure. As used herein, singular forms of “a”, “an” and “the” are also intended to include plural forms, unless the context clearly indicates otherwise. It should also be understood that the terms “include” and/or “comprise”, when used in this specification, determine the presence of said features, integers, steps, operations, elements and/or components, but do not exclude the presence or addition of one or more other features, integers, steps, operations, elements, components and/or groups. As used herein, the term “and/or” includes anyone and all combinations of related listed items.

For a thorough understanding of the disclosure, detailed steps and detailed structures will be put forward in the following description to explain the technical scheme of the disclosure. The detailed description of the preferred embodiments of the disclosure is as follows, however, in addition to these detailed descriptions, the disclosure may have other embodiments.

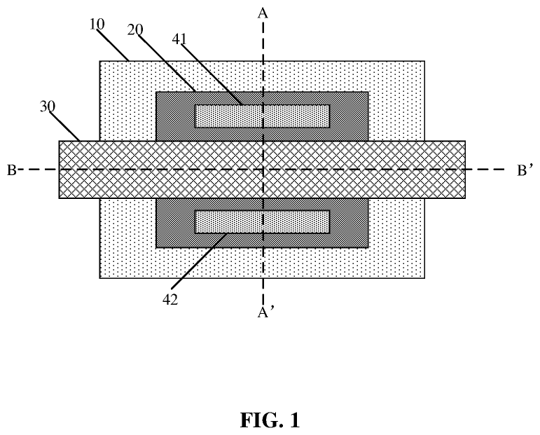

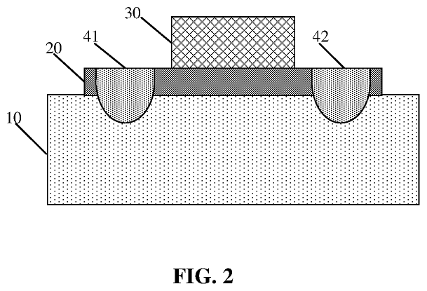

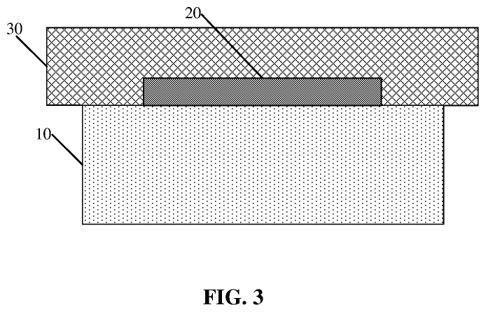

An embodiment of the disclosure provides a semiconductor device. FIG. 1 is a top view of a semiconductor device provided by an embodiment of the disclosure, FIG. 2 is a cross-sectional view along the dotted line A-A′ in FIG. 1, and FIG. 3 is a cross-sectional view along the dotted line B-B′ in FIG. 1.

Referring to FIGS. 1 to 3, the semiconductor device includes: a substrate 10; a semiconductor material layer 20 located on the substrate 10 and covering a part of the substrate 10; a gate 30 located on the semiconductor material layer 20 and the substrate 10 not covered by the semiconductor material layer 20; in which a width of the semiconductor material layer 20 is smaller than a width of the substrate 10 along an extending direction of the gate 30, and a carrier mobility of the material of the semiconductor material layer 20 and a carrier mobility of the material of the substrate 10 are different.

In the embodiment of the disclosure, by forming the semiconductor material layer with the width smaller than the width of the substrate along the extension direction of the gate, and according to the difference between the carrier mobility of the semiconductor material layer and the carrier mobility of the substrate, a control device with at least three states is provided, which at least includes three states of off, semi-conducting and full-conducting. In practical circuit application, it can switch various working states according to the voltage and reduce GIDL current.

The substrate 10 may be an elementary semiconductor material substrate (such as silicon (Si) substrate, germanium (Ge) substrate, etc.), a composite semiconductor material substrate (such as silicon germanium (SiGe) substrate, etc.), or a silicon-on-insulator (SOI) substrate, germanium-on-insulator (GeOI) substrate, etc. In the embodiment of the disclosure, the substrate 10 is a silicon substrate.

In an embodiment, the carrier mobility of the semiconductor material layer 20 is greater than the carrier mobility of the substrate 10 material, thus improving the carrier mobility of the channel region, optimizing the operation speed of the semiconductor device and improving the electrical performance of the semiconductor device.

The gate 30 may include an oxide layer, a first gate conductive layer, a second gate conductive layer and other structures (not shown in the figures) stacked in sequence.

In an embodiment, as shown in FIG. 1, the width of the semiconductor material layer 20 is smaller than the width of the substrate 10 along the direction perpendicular to the extension of the gate 30. In other embodiments, the width of the semiconductor material layer 20 may be equal to the width of the substrate 10 along a direction perpendicular to the extension of the gate 30.

In an embodiment, the material of the substrate 10 includes a first element, and the material of the semiconductor material layer 20 includes the first element and a second element different from the first element. In this way, because there is a difference between the materials of the substrate and the semiconductor material layer, the carrier mobility can be influenced, so that the threshold voltages of the channel regions respectively formed in the semiconductor material layer and the substrate are different.

In an embodiment, the first element is silicon and the second element is germanium. That is, the substrate 10 is a silicon substrate, and the semiconductor material layer 20 is a germanium silicon layer. There is a lattice difference between germanium and silicon, by which the carrier mobility may be affected and thus the threshold voltage of the channel region is adjusted. In other embodiments, the first element and the second element may also be selected from other elements that can affect the carrier mobility, such as but not limited to silicon, germanium, boron, tellurium, iodine, carbon, phosphorus, arsenic, sulfur and the like.

In other embodiments, the substrate 10 is a silicon substrate, and the semiconductor material layer 20 is a germanium silicon layer containing carbon.

In an embodiment, a percentage content of the second element in the semiconductor material layer 20 ranges from 20% to 40%. Therefore, in the range, the semiconductor material layer can better influence the carrier mobility and adjust the threshold voltage of the channel region, so that the formed third-stage control device can better reduce the GIDL current.

In an embodiment, the semiconductor material layer 20 includes a first semiconductor material layer and a second semiconductor material layer (not shown in the figures). The first semiconductor material layer and the second semiconductor material layer are arranged side by side, and both the first semiconductor material layer and the second semiconductor material layer extend along the direction from the source to the drain. The mobility of the material of the first semiconductor material layer, the mobility of the material of the second semiconductor material layer and the mobility of the material of the substrate are different. In this way, according to the difference in carrier mobility of the first semiconductor material layer, the second semiconductor material layer and the substrate, the semiconductor device can be formed into a device with more states.

In an embodiment, as shown in FIG. 3, the length of the gate 30 is longer than the length of the substrate 10 along the extending direction of the gate 30, that is, the gate 30 may be located on other structures, so the length of the gate 30 is longer than the length of the substrate 10. In this way, the control ability of the channel region can be improved, and the leakage problem of devices can be improved, meanwhile multiple device structures can share the same gate.

In an embodiment, the semiconductor device includes three states. When the voltage applied to the semiconductor device is less than a first threshold, the semiconductor device is in the off state. When the voltage is greater than the first threshold and less than a second threshold, the semiconductor device is in a semi-conducting state. When the voltage is greater than the second threshold, the semiconductor device is in a full-conducting state.

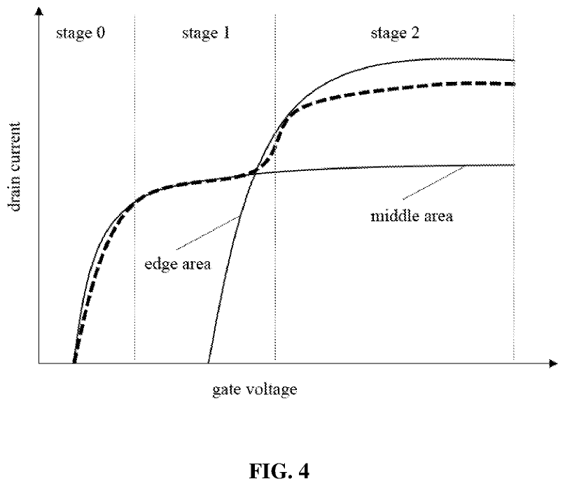

Specifically, as shown in FIG. 1, since the width of the semiconductor material layer 20 in the direction extending along the gate 30 is smaller than the width of the substrate 10, the channel region of the semiconductor device is divided into two parts, one part is the middle area covered by the semiconductor material layer 20, and the other part is the edge area not covered by the semiconductor material layer 20. Since the semiconductor material layer 20 only partially grows on the substrate 10, the threshold voltage of the channel region in the middle area covered by the semiconductor material layer 20 is low, and the middle area can be turned on in advance. When the voltage reaches the threshold voltage of the edge area, the channel in the edge area can be turned on. Finally the voltage versus current curve formed is shown in FIG. 4.

Referring to FIG. 4, in stage 0, the voltage of the semiconductor device is less than the first threshold, and neither the middle area nor the edge area reaches the on state, so the semiconductor device is in the off state; in stage 1, the voltage of the semiconductor device is greater than the first threshold and less than the second threshold, and the middle region reaches the on state, while the edge area is still in the off state, so the semiconductor device is in the semi-conducting state, and redundancy to the gate voltage is high, and the drain current does not change due to slight fluctuation of the gate voltage; in stage 2, the voltage of the semiconductor device is greater than the second threshold, and both the middle area and the edge area reach the on state, so the semiconductor device is in the full-conducting state and operates in the saturation region. The three states of the semiconductor device are shown by the dotted line in FIG. 4. Thus, the semiconductor device provided by an embodiment of the disclosure is a control device with three states.

In an embodiment, as shown in FIG. 2, the semiconductor device further includes a source 41 and a drain 42, which are located on both sides of the gate 30 and penetrate through the semiconductor material layer 20 and extend into the substrate 10.

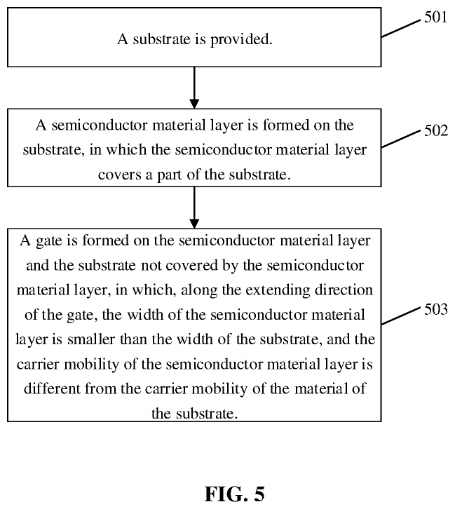

In an embodiment of the disclosure, a method for manufacturing a semiconductor device is also provided. For details, please refer to FIG. 5. As shown in the figure, the method includes the following operations.

In the operation 501, a substrate is provided.

In the operation 502, a semiconductor material layer is formed on the substrate, in which the semiconductor material layer covers a part of the substrate.

In the operation 503, a gate is formed on the semiconductor material layer and the substrate not covered by the semiconductor material layer, in which, along the extending direction of the gate, the width of the semiconductor material layer is smaller than the width of the substrate, and the carrier mobility of the material of the semiconductor material layer is different from the carrier mobility of the material of the substrate.

Next, the method for manufacturing a semiconductor device provided by the embodiment of this disclosure is described in further detail in combination with the specific embodiment.

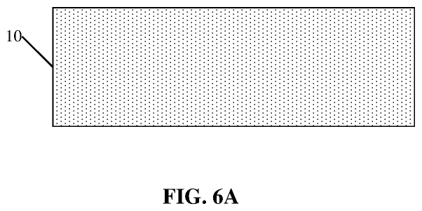

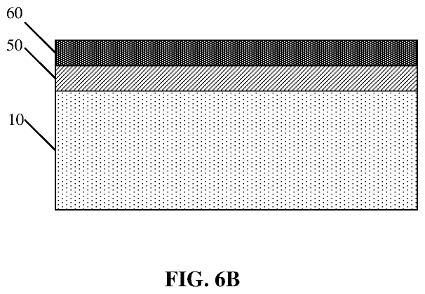

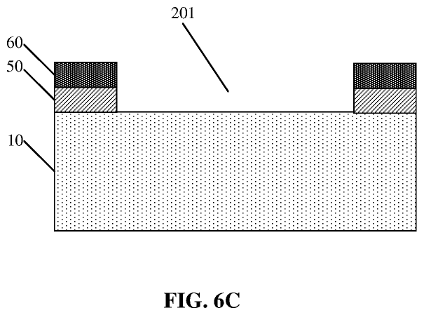

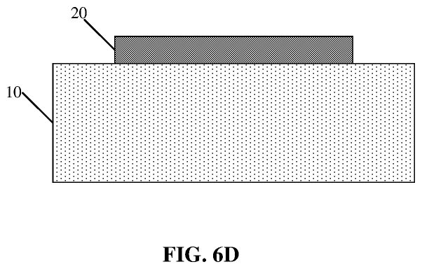

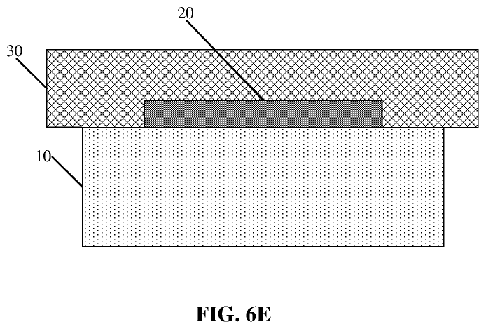

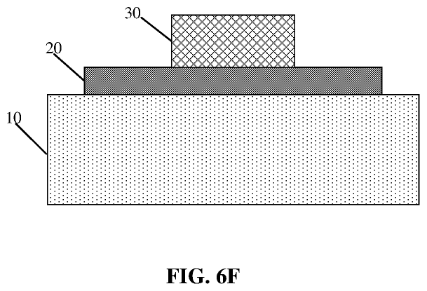

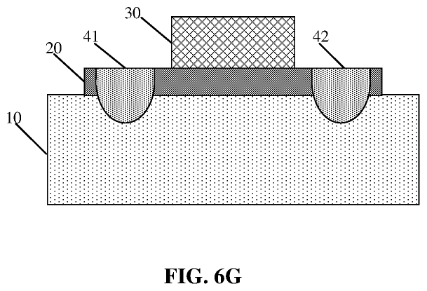

FIGS. 6A to 6G are schematic structural diagrams of a semiconductor device provided by the embodiment of the disclosure in the manufacturing process.

It should be noted that FIGS. 6A to 6E are sectional views along the dotted line B-B′ in FIG. 1, and FIGS. 6F to 6G are sectional views along the dotted line A-A′ in FIG. 1.

First, referring to FIG. 6A, the operation 501 is performed to provide a substrate 10. The substrate 10 may be an elementary semiconductor material substrate (such as silicon (Si) substrate, germanium (Ge) substrate, etc.), a composite semiconductor material substrate (such as silicon germanium (SiGe) substrate, etc.), or a silicon-on-insulator (SOI) substrate, germanium-on-insulator (GeOI) substrate, etc. In the embodiment of the disclosure, the substrate 10 is the silicon substrate.

Next, referring to FIGS. 6B to 6D, the operation 502 is performed. A semiconductor material layer 20 is formed on the substrate 10, and the semiconductor material layer 20 covers a part of the substrate 10.

In practice, referring to FIG. 6B, a mask layer 50 may be formed on the substrate 10 firstly, and then a photoresist layer 60 may be formed on the mask layer 50 covering the substrate 10.

In an embodiment, the mask layer 50 may be a composite material layer of silicon dioxide and silicon nitride.

Then, the photoresist layer 60 is exposed and developed to transfer a preset pattern of the semiconductor material layer on a photomask (not shown in the figure) to the photoresist layer 60, forming a patterned photoresist layer.

Referring to FIG. 6C, based on the patterned photoresist layer, the part of the mask layer 50 corresponding to the preset pattern of the semiconductor material layer is etched to expose a part of the substrate 10. In an embodiment, the mask layer and the photoresist layer located in the middle area of the substrate 10 are removed to expose the middle area of the substrate 10.

Optionally, the photoresist layer 60 is a positive photoresist or a negative photoresist. The positive photoresist may form soluble substances after illumination, while the negative photoresist forms insoluble substances after illumination.

Referring to FIG. 6D, the semiconductor material layer 20 is formed on the exposed substrate 10. After forming the semiconductor material layer 20, the remaining photoresist layer 60 and mask layer 50 are removed.

In the embodiment of the disclosure, the photomask for forming the semiconductor material layer may be formed by modifying the photomask in the previous process, such as a PMOS mask, without adding a new photomask. In this way, the process can be reduced and the cost can be saved.

In the embodiment shown in FIGS. 6B to 6D, the semiconductor material layer 20 is formed by a method for forming the photoresist layer, and in other embodiments, the semiconductor material layer 20 may also be formed by an in-situ doping epitaxial process.

The semiconductor material layer 20 is formed by the in-situ doping epitaxial process, in which growth rates of the semiconductor material layer 20 in the middle area and the edge area of the substrate 10 are adjusted by controlling the flow rate of growth gas, so as to make the semiconductor material layer 20 cover a part of the substrate 10.

Particularly, the growth gas includes HCL, SiH₄ and GeH₄. Different percentage contents of germanium atoms can be obtained by adjusting the flow ratio of HCL, SiH₄ and GeH₄, and the germanium atoms are evenly distributed, the process step is simple, and the uniformity of the formed semiconductor material layer is good.

In an embodiment, the material of the substrate 10 includes a first element, and the material of the semiconductor material layer 20 includes the first element and a second element different from the first element. In this way, because there is a difference between the materials of the substrate 10 and the semiconductor material layer 20, the carrier mobility can be influenced, and then the threshold voltages of the channel regions in the semiconductor material layer 20 and the substrate 10 are different.

In an embodiment, the first element is silicon and the second element is germanium. That is, the substrate 10 is a silicon substrate, and the semiconductor material layer 20 is a germanium silicon layer. There is a lattice difference between germanium and silicon, by which the carrier mobility can be affected and thus the threshold voltage of the channel region is adjusted. In other embodiments, the first element and the second element may also be selected from other elements that can affect the carrier mobility, such as but not limited to silicon, germanium, boron, tellurium, iodine, carbon, phosphorus, arsenic, sulfur and the like.

In other embodiments, the substrate 10 is a silicon substrate, and the semiconductor material layer 20 is a germanium silicon layer containing carbon.

In an embodiment, a percentage content of the second element in the semiconductor material layer ranges from 20% to 40%. Therefore, in the range, the semiconductor material layer can better influence the carrier mobility and adjust the threshold voltage of the channel region, so that the formed control device with three states can better reduce the GIDL current.

Next, refer to FIG. 6E and FIG. 6F. It should be noted that FIG. 6E is a sectional view along the dotted line B-B′ in FIG. 1, and FIG. 6F is a sectional view along the dotted line A-A′ in FIG. 1. The operation 503 is performed, a gate 30 is formed on the semiconductor material layer 20 and the substrate 10 not covered by the semiconductor material layer 20; in which the width of the semiconductor material layer 20 is smaller than the width of the substrate 10 along the extending direction of the gate 30, and the carrier mobility of the material of the semiconductor material layer 20 is different from that of the substrate 10.

In an embodiment, the carrier mobility of the semiconductor material layer 20 is greater than the carrier mobility of the material of the substrate 10, thus improving the carrier mobility of the channel region, optimizing the operation speed of the semiconductor device and improving the electrical performance of the semiconductor device.

In practice, the formation of the gate 30 specifically includes: firstly, a mask layer (not shown in the figures) can be formed on the semiconductor material layer 20 and the substrate 10 not covered by the semiconductor material layer 20, and then the mask layer is patterned, to bring out the gate trench pattern to be etched in the mask layer, and the mask layer may be patterned by photolithography technique. The mask layer may be a photoresist mask or a hard mask patterned based on a photolithography mask. When the mask layer is the photoresist mask, the mask layer is specifically patterned through the operations of exposure, development, removing of photoresist and the like. Then, the gate trench with a certain depth is etched according to the pattern of the gate trench to be etched. Then, the gate is formed in the gate trench, and the redundant mask layer is removed.

The gate 30 may include an oxide layer, a first gate conductive layer, a second gate conductive layer and other structures (not shown in the figures) stacked in sequence.

In an embodiment, the semiconductor device includes three states, and when a voltage applied to the semiconductor device is less than a first threshold, the semiconductor device is in an off state; when the voltage is greater than the first threshold and less than a second threshold, the semiconductor device is in a semi-conducting state; when the voltage is greater than the second threshold, the semiconductor device is in a fully full-conducting state.

Specifically, as shown in FIG. 1, since the width of the semiconductor material layer 20 in the direction extending along the gate 30 is smaller than the width of the substrate 10, the channel region of the semiconductor device is divided into two parts, one part is the middle area covered by the semiconductor material layer 20, and the other part is the edge area not covered by the semiconductor material layer 20. Since the semiconductor material layer 20 only grows on part of the substrate 10, the threshold voltage of the channel region in the middle region covered by the semiconductor material layer 20 is relatively low, and the middle area will be turned on in advance. When the voltage reaches the threshold voltage of the edge area, the channel in the edge area is turned on. Finally, the voltage versus current curve formed is shown in FIG. 4.

Referring to FIG. 4, in stage 0, the voltage of the semiconductor device is less than the first threshold, and neither the middle area nor the edge area reaches the on state, so the semiconductor device is in the off state; in stage 1, the voltage of the semiconductor device is greater than the first threshold and less than the second threshold, and the middle region reaches the on state, while the edge area is still in the off state, so the semiconductor device is in the semi-conducting state, and redundancy to the gate voltage is high, and the drain current does not change due to slight fluctuation of the gate voltage; in stage 2, the voltage of the semiconductor device is greater than the second threshold, and both the middle area and the edge area reach the on state, and thus the semiconductor device is in full-conducting state and operates in the saturation region. The three states of the semiconductor device are shown by the broken line in FIG. 4. Therefore, the semiconductor device provided by the embodiment of this disclosure is a control device with three states.

In an embodiment, as shown in FIG. 6E, the length of the gate 30 is greater than the length of the substrate 10 along the extending direction of the gate 30, that is, the gate 30 may be located on other structures, and thus the length of the gate 30 is greater than the length of the substrate 10. In this way, the control ability of the channel region can be improved, and the device leakage problem can be improved; meanwhile multiple device structures can share the same gate.

Next, referring to FIG. 6G, the semiconductor material layer 20 on both sides of the gate 30 and the substrate 10 under the semiconductor material layer 20 are ion doped to form the source 41 and the drain 42 penetrating through the semiconductor material layer 20 and extending into the substrate 10.

Specifically, in an embodiment, a lightly doped drain region implantation process (LDD), a source/drain region (S/D) ion implantation and an annealing process may be sequentially performed, so that the source 41 and the drain 42 are formed on both sides of the gate 30; the specific process parameters may be set according to actual process requirements, which is not limited in this disclosure.

In an embodiment, the semiconductor material layer 20 includes a first semiconductor material layer and a second semiconductor material layer (not shown in the figures). The first semiconductor material layer and the second semiconductor material layer are arranged side by side, and both the first semiconductor material layer and the second semiconductor material layer extend along the direction from the source to the drain. The mobility of the material of the first semiconductor material layer, the mobility of the material of the second semiconductor material layer and the mobility of the material of the substrate are different. In this way, according to the difference in carrier mobility of the first semiconductor material layer, the second semiconductor material layer and the substrate, the semiconductor device can be formed into a device with more states.

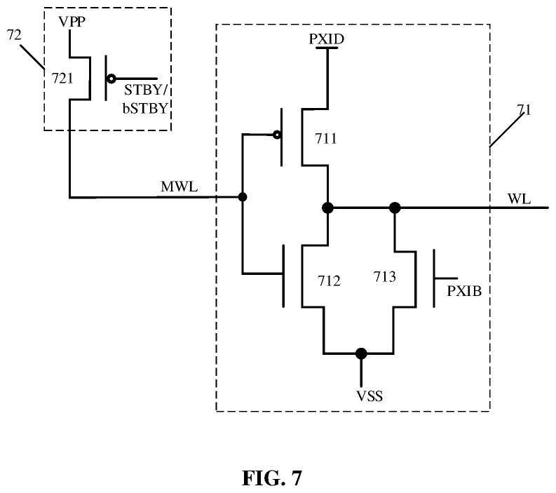

In an embodiment of the disclosure, a circuit is further provided, in which the above semiconductor device is applied. As shown in FIG. 7, the circuit includes: a main word line MWL, a sub word line WL, a word line driving circuit 71 and a voltage control module 72, and the voltage control module 72 includes the semiconductor device 721 as described in anyone of the above embodiments.

The semiconductor device 721 includes a source terminal, a drain terminal and a gate terminal. The source terminal is connected to the high level signal VPP, the drain terminal is connected to the main word line MWL, and the gate terminal is connected to the standby signal STBY.

The word line driving circuit 71 is connected between the main word line MWL and the sub word line WL.

The voltage control module 72 is configured to reduce the voltage output to the word line driving circuit 71 when the standby state occurs.

In the traditional circuit, the main word line MWL is at a high level, the sub word line WL is at a low level, and there is a voltage difference between the gate and the source or drain of the first PMOS transistor 711, which will cause the first PMOS transistor 711 to be affected by GIDL current. Therefore, in the embodiment of this disclosure, the voltage control module 72 is added to the main word line MWL, in this way, in the standby state, the semiconductor device can be controlled in the state of stage 1 as shown in FIG. 4, that is, the semi-conducting state, so that the equivalent resistance of the semiconductor device increases and then the voltage output to the word line driving circuit 71 is reduced, reducing the GIDL current.

The semiconductor device 721 is a PMOS transistor.

In an embodiment, the word line driving circuit 71 includes a first PMOS transistor 711, a first NMOS transistor 712 and a second NMOS transistor 713. The gates of the first PMOS transistor 711 the first NMOS transistor 712 are connected and are connected to the main word line MWL; the source of the first NMOS transistor 712 and the source of the second NMOS transistor 713 are connected and are grounded. The drain of the first PMOS transistor 711, the drain of the first NMOS transistor 712 and the drain of the second NMOS transistor 713 are connected and are connected to the sub-word line WL.

In an embodiment, the first PMOS transistor 711 and the first NMOS transistor 712 are formed to be an inverting circuit. The inverting circuit has an input terminal connected to the main word line MWL and an output terminal connected to the sub word line WL. The source of the first PMOS transistor 711 may be connected to the sub word line driving signal PXID. The second NMOS transistor 713 is coupled between the output terminal of the inverting circuit and the ground terminal VSS. The gate of the second NMOS transistor 713 is connected to the inverting sub word line driving signal PXIB and responds to the inverting sub word line driving signal PXIB.

In an embodiment of the disclosure, a method for driving a circuit is also provided, which is applied to the circuit described in anyone of the above embodiments; the method includes controlling the semiconductor device to be in the off state when the standby state does not occur; and controlling the semiconductor device to be in the semi-conducting state when the standby state occurs, so as to increase the equivalent resistance of the semiconductor device and reduce the voltage output to the word line driving circuit.

What has been described above is only the preferred embodiment of this disclosure, and it is not intended to limit the scope of protection of this disclosure. Any modification, equivalent replacement and improvement within the spirit and principle of this disclosure should be included within the scope of protection of this disclosure.

### INDUSTRIAL APPLICATION

In the embodiments of the disclosure, by forming a semiconductor material layer with a width smaller than a width of the substrate along an extension direction of the gate, and according to the difference between the carrier mobility of the semiconductor material layer and the carrier mobility of the substrate, a control device with at least three states is provided, which at least includes three states of off, semi-conducting and full- conducting. In practical circuit application, it can switch various working states according to the voltage and reduce GIDL current.

1. A semiconductor device, comprising:
a substrate;
a semiconductor material layer located on the substrate and covering a part of the substrate; and
a gate located on the semiconductor material layer and the substrate not covered by the semiconductor material layer, wherein,
along an extension direction of the gate, a width of the semiconductor material layer is smaller than a width of the substrate, and a carrier mobility of a material of the semiconductor material layer is different from a carrier mobility of a material of the substrate.

2. The semiconductor device according to claim 1, wherein,
the material of the substrate comprises a first element, and the material of the semiconductor material layer comprises the first element and a second element different from the first element.

3. The semiconductor device according to claim 2, wherein,
the first element is silicon and the second element is germanium.

4. The semiconductor device according to claim 2, wherein,
a percentage content of the second element in the semiconductor material layer ranges from 20% to 40%.

5. The semiconductor device according to claim 1, wherein,
the semiconductor device includes three states, and in the case that a voltage applied to the semiconductor device is less than a first threshold, the semiconductor device is in an off state; in the case that the voltage is greater than the first threshold and less than a second threshold, the semiconductor device is in a semi-conducting state; in the case that the voltage is greater than the second threshold, the semiconductor device is in a full-conducting state.

6. The semiconductor device according to claim 1, further comprising:
a source and a drain, which are respectively located on both sides of the gate and penetrate through the semiconductor material layer and extend into the substrate.

7. A method for manufacturing a semiconductor device, comprising:
providing a substrate;
forming a semiconductor material layer on the substrate, wherein the semiconductor material layer covers a part of the substrate; and
forming a gate on the semiconductor material layer and the substrate not covered by the semiconductor material layer, wherein,
a width of the semiconductor material layer is smaller than a width of the substrate along an extension direction of the gate, and a carrier mobility of a material of the semiconductor material layer is different from a carrier mobility of a material of the substrate.

8. The method according to claim 7, wherein,
the material of the substrate includes a first element, and the material of the semiconductor material layer includes the first element and a second element different from the first element.

9. The method according to claim 8, wherein,
the first element is silicon and the second element is germanium.

10. The method according to claim 8, wherein,
a percentage content of the second element in the semiconductor material layer ranges from 20% to 40%.

11. The method according to claim 7, wherein,
a semiconductor material layer is formed by an in-situ doping epitaxial process, in which growth rates of the semiconductor material layer in a middle area and an edge area of the substrate are adjusted by controlling a flow rate of a growth gas, so that the semiconductor material layer covers part of the substrate.

12. The method according to claim 7, wherein,
a photoresist layer is formed on a mask layer covering the substrate;
the photoresist layer is exposed and developed, to transfer a preset pattern of the semiconductor material layer in a photomask to the photoresist layer;
a portion of the mask layer corresponding to the preset pattern of the semiconductor material layer is removed to expose part of the substrate; and
the semiconductor material layer is formed on the exposed substrate.

13. The method according to claim 7, further comprising:
performing ion doping on the semiconductor material layer on both sides of the gate and the substrate under the semiconductor material layer to form a source and a drain penetrating through the semiconductor material layer and extending into the substrate.

14. A circuit comprising:
a main word line, a sub word line, a word line driving circuit and a voltage control module, wherein the voltage control module comprises the semiconductor device according to claim 1, wherein,
the semiconductor device comprises a source terminal, a drain terminal and a gate terminal; the source terminal is connected to a high-level signal, the drain terminal is connected to a main word line, and the gate terminal is connected to a standby signal;
the word line driving circuit is connected between the main word line and the sub word line; and
the voltage control module is configured to reduce a voltage output to the word line driving circuit in the case that a standby state occurs.

15. The circuit according to claim 14, wherein,
the material of the substrate comprises a first element, and the material of the semiconductor material layer comprises the first element and a second element different from the first element.

16. The circuit according to claim 15, wherein,
the first element is silicon and the second element is germanium.

17. The circuit according to claim 15, wherein,
a percentage content of the second element in the semiconductor material layer ranges from 20% to 40%.

18. The circuit according to claim 14, wherein,
the word line driving circuit comprises a first PMOS transistor, a first NMOS transistor and a second NMOS transistor; gates of the first PMOS transistor and the first NMOS transistor are connected and are connected to the main word line; a source of the first NMOS transistor and a source of the second NMOS transistor are connected and are grounded; a drain of the first PMOS transistor, the drain of the first NMOS transistor and the drain of the second NMOS transistor are connected and are connected to the sub word line.

19. A method for driving a circuit, wherein the method for driving a circuit, is used to the circuit according to claim 14, and the method comprises:
controlling the semiconductor device to be in an off state in the case that the standby state does not occur; and
controlling the semiconductor device to be in a semi-conducting state in the case that the standby state occurs to increase an equivalent resistance of the semiconductor device and reduce a voltage output to the word line driving circuit.

20. A method for driving a circuit, wherein the method for driving a circuit, is used to the circuit according to claim 18, and the method comprises:
controlling the semiconductor device to be in an off state in the case that the standby state does not occur; and
controlling the semiconductor device to be in a semi-conducting state in the case that the standby state occurs to increase an equivalent resistance of the semiconductor device and reduce a voltage output to the word line driving circuit.
